(19) United States
(12) Patent Application Publication
(10) Pub. No.: US 2026/0201594 A1
(43) Pub. Date: Jul. 16, 2026

(54) METHOD FOR PREPARING ONE OR MULTIPLE LARGE-AREA CONTINUOUS GRAPHENE MONOLAYERS AND STRUCTURE PREPARED THEREBY

(71) Applicant: Leap Semiconductor Corp., Taoyuan City (TW)

(72) Inventors: Wen-Chung LI, Taoyuan City (TW); Kai-Chi HSIAO, Taoyuan City (TW); Chi-Ming YANG, Taoyuan City (TW)

(21) Appl. No.: 19/192,508

(22) Filed: Apr. 29, 2025

(30) Foreign Application Priority Data
Jan. 10, 2025 (TW) 114101069

(51) Int. Cl. C25D 11/32; C23C 8/20; C30B 29/06; C30B 33/00

(52) U.S. Cl. CPC C25D 11/32; C23C 8/20; C30B 29/06; C30B 33/00

(57) ABSTRACT

A method for preparing a graphene layer includes: subjecting a single crystal silicon substrate to a carburizing treatment at a temperature ranging from 600° C. to 1200° C., so as to obtain an intermediate structure including the single crystal silicon substrate and a 3C-SiC layer formed on the single crystal silicon substrate; placing the intermediate structure in a molten electrolyte of an electrolysis apparatus to permit the intermediate structure to serve as an anode, and applying a predetermined voltage to cause silicon atoms in the 3C-SiC layer to undergo electrolytic dissociation, such that the silicon atoms move out from lattice positions in the 3C-SiC layer and carbon atoms remaining in the lattice positions are rearranged to form a graphene layer which is a continuous graphene monolayer or a plurality of continuous graphene layers. The structure including the graphene layer prepared by the method is also provided.

### CROSS-REFERENCE TO RELATED APPLICATION

This application claims priority to Taiwanese Invention Patent Application No. 114101069, filed on Jan. 10, 2025, the entire disclosure of which is incorporated by reference herein.

### FIELD

The present disclosure relates to a method for preparing one or multiple large-area continuous graphene monolayers. The present disclosure also relates to a structure prepared by the method.

### BACKGROUND

Graphene is an ideal choice of material for different types of electronic components due to its various properties. For example, the high mobility and saturation velocity of graphene have attracted the attention of those skilled in the radio-frequency electronic component industry. In the application of digital logic devices, graphene is primarily used as a material for making channels of field-effect transistors (abbreviated as “FETs” hereinafter). Since the two-dimensional structure of graphene is maintained in a single-layer state (i.e., a graphene monolayer), the channels become thinner and are more easily controlled by the gate. Therefore, when the size of FETs shrinks, the short channel effect becomes more evident, and use of graphene as a material for making the channels can mitigate this negative effect. In addition, graphene also becomes an excellent choice of material for transparent conductive films (abbreviated as “TCFs” hereinafter) because of its high visible light transparency, excellent electronic transport properties, mechanical strength, and environmental friendliness. However, conventional methods, such as mechanical exfoliation, pre-preparation on metal and transfer, and other manufacturing techniques, for preparing a high-quality, intact and continuous graphene monolayer with a large surface area are very challenging, which greatly limits practical applications thereof.

For example, in the pre-preparation on metal and transfer technique, a copper foil can be used as a substrate for growing graphene. To be specific, hydrogen (H₂) and argon (Ar) gases are introduced into a quartz tube by chemical vapor deposition (CVD) after removal of residual gas therein, and the temperature is raised to 1000° C. within 50 minutes, so as to allow the copper foil to be annealed at 1000° C. for 30 minutes. Afterwards, 1 sccm of methane (CH₄) is introduced into the quartz tube and maintained for 10 minutes so as to form a plurality of nucleation sites on the annealed copper foil. Thereafter, 3 sccm of CH₄ is introduced into the quartz tube and maintained for 40 minutes so as to allow growth of a graphene monolayer on the nucleation sites. Finally, a roll-to-roll transfer method is employed to transfer the graphene monolayer onto a semiconductor substrate of an electronic component (e.g., FET), so that the graphene monolayer serves as the channel for the electronic component. Although the roll-to-roll transfer method is capable of transferring the graphene monolayer onto the semiconductor substrate, it is well known that the graphene monolayer is prone to fractures and damages during such transfer process, resulting in the electronic transport properties of the thus transferred graphene monolayer being adversely affected.

A technique capable of producing intact and continuous graphene films having large surface area is the thermal decomposition method. The thermal decomposition method involves heating a single crystal silicon carbide (SiC) substrate to a high temperature of greater than 1400° C., such that silicon atoms on the surface of the single crystal silicon substrate are removed and carbon atoms remaining on the surface are rearranged to form a graphene film under the high temperature. Although the thermal decomposition method is capable of producing intact and continuous graphene films having large surface area, those skilled in the power semiconductor industry are well aware that single crystal silicon carbide substrates are not only expensive, but also the high temperature of 1400° C. required to obtain the graphene films would results in energy loss and increased production cost. Therefore, the cost of graphene films produced by the thermal decomposition method is high.

In view of the aforesaid, those skilled in the art endeavor to improve the method for preparing a graphene layer having relatively large surface area which may be a continuous graphene monolayer or a plurality of continuous graphene layers, so as to maintain the integrity and to reduce the production cost of graphene.

### SUMMARY

Therefore, an object of the present disclosure is to provide a method for preparing one or multiple large-area continuous graphene monolayers, and a structure including the one or multiple large-area continuous graphene monolayers that can alleviate at least one of the drawbacks of the prior art.

According to an aspect of the present disclosure, the method for preparing a graphene layer includes the steps of:
(a) subjecting a single crystal silicon substrate to a carburizing treatment at a carburizing temperature ranging from 600° C. to 1200° C., so as to obtain an intermediate structure including the single crystal silicon substrate and a 3C-SiC layer that is formed on a surface of the single crystal silicon substrate; and
(b) placing the intermediate structure in a molten electrolyte of an electrolysis apparatus to permit the intermediate structure to serve as an anode, and applying a predetermined voltage to the anode to cause silicon atoms in the 3C-SiC layer to undergo electrolytic dissociation, such that the silicon atoms move out from lattice positions in the 3C-SiC layer and such that carbon atoms remaining in the lattice positions are rearranged to form a graphene layer, the graphene layer being a continuous graphene monolayer or a plurality of continuous graphene layers.

According to another aspect of the present disclosure, the structure includes a single crystal silicon substrate, and a graphene layer covering a surface of the single crystal silicon substrate. The graphene layer is a continuous graphene monolayer or a plurality of continuous graphene layers.

### BRIEF DESCRIPTION OF THE DRAWINGS

Other features and advantages of the present disclosure will become apparent in the following detailed description of the embodiment(s) with reference to the accompanying drawings. It is noted that various features may not be drawn to scale.

FIG. 1 is a schematic view illustrating implementation of step (a) of a method for preparing a graphene layer according to a first embodiment of the present disclosure.

FIG. 2 is a schematic view illustrating implementation of step (b) of the method for preparing a graphene layer according to the first embodiment of the present disclosure.

FIG. 3 is a schematic view illustrating a structure including the graphene layer which is obtained by the method according to the first embodiment of the present disclosure.

FIG. 4 is a schematic view illustrating implementation of step (a) of the method for preparing a graphene layer according to a second embodiment of the present disclosure.

### DETAILED DESCRIPTION

Before the present disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

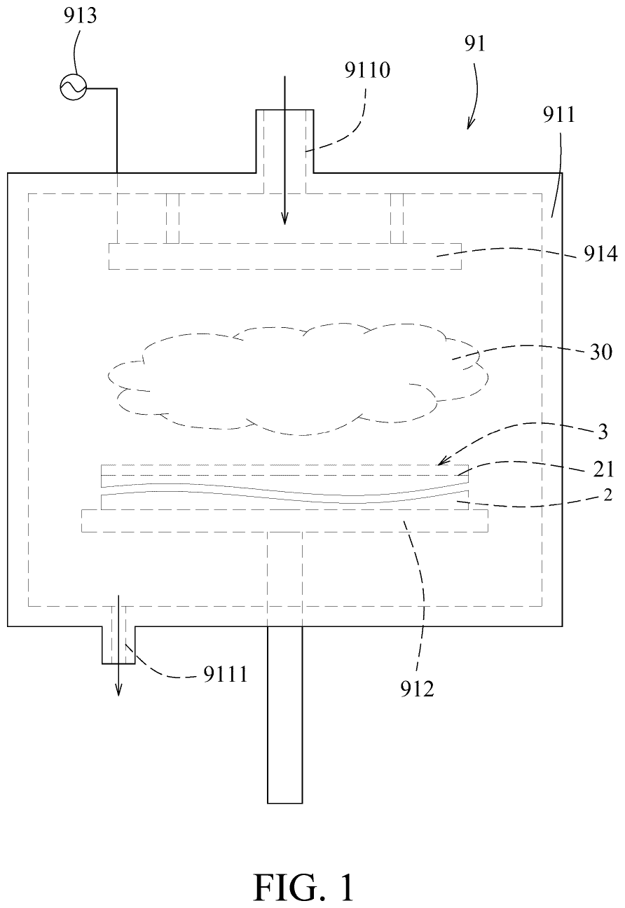

Referring to FIGS. 1 to 3, the present disclosure provides a method for preparing a graphene layer 4 according to a first embodiment, and a structure including the graphene layer 4 prepared thereby. The graphene layer 4 includes one or multiple large-area continuous graphene monolayers. The method for preparing a graphene layer of the first embodiment includes steps (a) and (b).

As shown in FIG. 1, in step (a), a single crystal silicon substrate 2 is subjected to a carburizing treatment at a carburizing temperature ranging from 600° C. to 1200° C., so as to obtain an intermediate structure including the single crystal silicon substrate 2 and a 3C-SiC layer 3 that is formed on a surface 21 of the single crystal silicon substrate 2. In this embodiment, examples of the single crystal silicon substrate 2 may include, but are not limited to, an 8-inch silicon wafer and a 12-inch silicon wafer. It should be noted that, the 3C-SiC of the 3C-SiC layer 3 is known as β-phase silicon carbide in the semiconductor industry, and has a zinc blende (cubic) crystal structure.

In step (a) of the method of the first embodiment, the single crystal silicon substrate 2 is placed in a vacuum chamber 911 and a radio frequency voltage is applied across the vacuum chamber 911 to decompose a carbon source 30 in the vacuum chamber 911, such that the decomposed carbon source 30 diffuses to the surface 21 of the single crystal silicon substrate 2 during the carburization treatment performed at the carburizing temperature. Therefore, in step (a) of the method of the first embodiment, carbon ions of the decomposed carbon source 30, which diffuse to the surface 21 of the single crystal silicon substrate 2, can chemically react with the silicon on the surface 21, so as to form the 3C-SiC layer 3 on the surface 21 of the single crystal silicon substrate 2.

To be specific, in step (a) of the method of the first embodiment, the single crystal silicon substrate 2 is placed on a carrier 912 in the vacuum chamber 911 of a plasma-enhanced chemical vapor deposition (abbreviated as PECVD hereinafter) system 91, in which the carrier 912 serves as a first electrode of the PECVD system 91. The single crystal silicon substrate 2 placed on the carrier 912 is then heated to the carburizing temperature by a heater (not shown) that is connected to the carrier 912 through a signal, and the carbon source 30 is introduced from a gas inlet 9110 of the vacuum chamber 911. Next, the radio frequency voltage is applied from a radio frequency power supply 913 of the PECVD system to a second electrode 914 of the PECVD system 91 so as to decompose the carbon source 30. In this case, a bias voltage ranging from −50 V and −500 V is applied to the carrier 912, so that the decomposed carbon source 30 diffuses to the surface 21 of the single crystal silicon substrate 2 at the carburizing temperature to chemically react with the silicon on the surface 21. The resultant residual gas is then extracted through a gas outlet 9111 of the vacuum chamber 911, so that a working pressure ranging from 0.1 Pa and 50.0 Pa is maintained in the vacuum chamber 911. The carbon source 30 suitable for use in step (a) of the method according to the present disclosure may include a hydrocarbon gas selected from the group consisting of methane (CH₄), ethylene (C₂H₄), acetylene (C₂H₂), and combinations thereof. In step (a) of the method of the first embodiment, the radio frequency applied from the radio frequency power supply 913 ranges from 10 MHz to 50 MHz, and the carburizing treatment is performed for a first predetermined time period of not greater than 2 hours, such that the 3C-SiC layer 3 formed on the surface 21 of the single crystal silicon substrate 2 has a first thickness ranging from 0.4 nm to 20.0 nm.

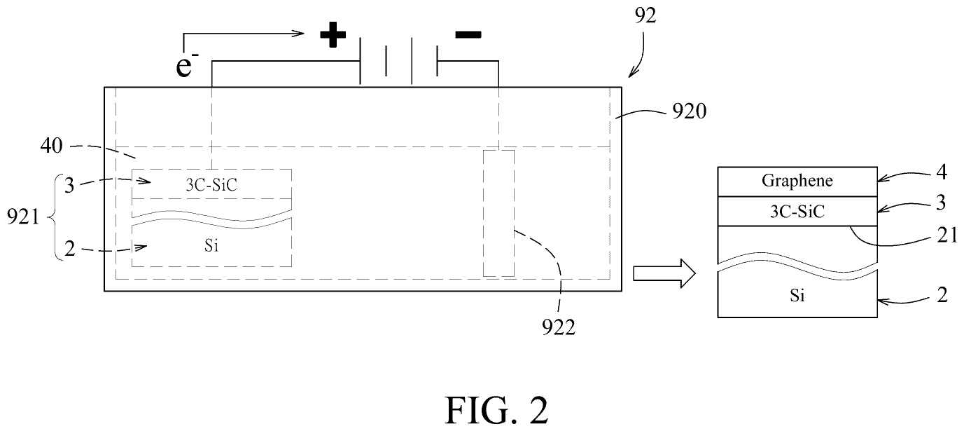

As shown in FIG. 2, the intermediate structure, which includes the single crystal silicon substrate 2 and the 3C-SiC layer 3, is placed in a molten electrolyte 40 of an electrolysis apparatus 92 to permit the intermediate structure to serve as an anode 921 of the electrolysis apparatus 92, and then a predetermined voltage is applied to the anode 921 to cause silicon atoms in the 3C-SiC layer 3 to undergo electrolytic dissociation, such that the silicon atoms move out from lattice positions in the 3C-SiC layer 3, and such that carbon atoms remaining in the lattice positions of the 3C-SiC layer 3 are rearranged to form a graphene layer 4. Therefore, in the method of the first embodiment, the graphene layer 4 is obtained by subjecting the silicon atoms in the 3C-SiC layer 3 to electrolytic dissociation on the surface 21 of the single crystal silicon substrate 2, and by rearrangement of the carbon atoms remaining in the lattice positions of the 3C-SiC layer 3. In some embodiments, after step (b), the remaining 3C-SiC layer 3 is located beneath the graphene layer 4, as shown in FIG. 2.

To be specific, in step (b) of the method of the first embodiment, the intermediate structure, which includes the single crystal silicon substrate 2 and the 3C-SiC layer 3, is placed in the molten electrolyte 40 in a reaction tank 920 of the electrolysis apparatus 92 to permit the intermediate structure to serve as the anode 921 of the electrolysis apparatus 92, and a graphite rod is placed in the molten electrolyte 40 to serve as a cathode 922 of the electrolysis apparatus 92. Next, the predetermined voltage is applied to the anode 921 and the cathode 922, causing silicon atoms in the 3C-SiC layer 3 to undergo electrolytic dissociation, such that the silicon atoms move out from lattice positions in the 3C-SiC layer 3, and such that carbon atoms remaining in the lattice positions of the 3C-SiC layer 3 are rearranged to form the graphene layer 4. In step (b) of the method of the first embodiment, the predetermined voltage ranges from 1 V to 10 V, and is applied for a second predetermined time period of not greater than 1 hour, such that the graphene layer 4 thus obtained has a second thickness ranging from 0.3 nm to 20.0 nm.

It should be noted that, in step (b), rearrangement of the carbon atoms to form the graphene layer 4 still relies on the driving force of temperature. Therefore, in step (b) of the method of the first embodiment, the molten electrolyte 40 is prepared from an inorganic salt that has a melting temperature of not lower than 600° C. and not greater than 1400° C. The inorganic salt suitable for use in the method according to present disclosure may include an inorganic chloride compound selected from a group IA inorganic chloride compound and a group IIA inorganic chloride compound. Examples of the inorganic chloride compound may include, calcium chloride (CaCl₂), potassium chloride (KCl), and lithium chloride (LiCl). In the first embodiment, the inorganic chloride compound is CaCl₂, and in step (b), the temperature of the reaction tank 920 is elevated to be not lower than 772° C. (i.e., the melting temperature of CaCl₂), such that CaCl₂ in solid form is melted into liquid form, and the carbon atoms are rearranged to form the graphene layer 4 at the temperature of approximately 772° C.

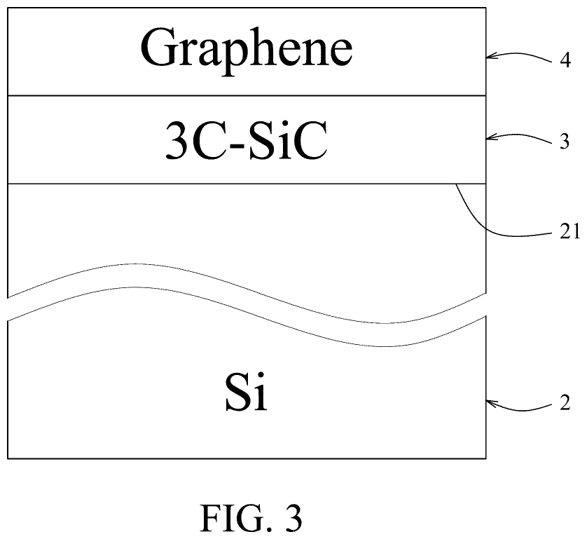

From the description above, in the method of the first embodiment according to the present disclosure, a silicon wafer having a relatively large surface area (8-inch or 12-inch) is utilized as the single crystal silicon substrate 2, and the 3C-SiC layer 3 is first formed on the surface 21 of the single crystal silicon substrate 2 in step (a), followed by rearrangement of the carbon atoms remaining in the lattice positions of the 3C-SiC layer 3 so as to form the graphene layer 4 in step (b). Therefore, a surface area of the graphene layer 4 obtained in step (b) is same as or substantially the same as a surface area of the surface 21 of the single crystal silicon substrate 2. In addition, as shown in FIG. 3, a structure prepared by the method of the first embodiment according to the present disclosure includes the single crystal silicon substrate 2, the graphene layer 4 covering the surface 21 of the single crystal silicon substrate 2, and the 3C-SiC layer 3 that is formed on the surface 21 of the single crystal silicon substrate 2 and that is sandwiched between the single crystal silicon substrate 2 and the graphene layer 4. It is worth mentioning that, the graphene layer 4 is formed by rearranging the carbon atoms remaining on the surface of the 3C-SiC layer 3, and may be a continuous graphene monolayer or a plurality of continuous graphene layers having a relative large surface area. Therefore, the problem of graphene damage caused by the roll-to-roll transfer method will not occur. As such, the graphene layer 4 is suitable for use as a substrate for an electronic component (e.g., FETs).

The structure obtained by the method of the first embodiment according to the present disclosure includes, for example, the single crystal silicon substrate 2, the 3C-SiC layer 3, and the graphene layer 4. It should be noted that, when the 3C-SiC layer 3 is relatively thin, and the time period for implementing step (b) is sufficient to fully remove the silicon atoms in the 3C-SiC layer 3, only the carbon atoms remain in the lattice positions of the 3C-SiC layer 3. As such, the structure, which is obtained after the carbon atoms remaining in the lattice positions of the 3C-SiC layer 3 are rearranged to form the graphene layer 4, only includes the single crystal silicon substrate 2, and the graphene layer 4 covering the surface 21 of the single crystal silicon substrate 2.

Although the thermal decomposition method described in the Background section can avoid the problem of the graphene film being damaged during the transfer process, it should be noted that, in step (b) of the method of the first embodiment of the present disclosure, since the intermediate structure, which includes the single crystal silicon substrate 2 and the 3C-SiC layer 3, is placed in the molten electrolyte 40 (i.e., CaCl2 being melted into a liquid form at the temperature of approximately 772° C.) to permit the intermediate structure to serve as the anode 921 of the electrolysis apparatus 92, application of the predetermined voltage in the range described in the foregoing allows the amount of the carbon atoms remaining on the surface of the 3C-SiC layer 3 to be more easily controlled, so that the graphene layer 4 can be formed with an accurate thickness. That is, the electrolytic dissociation in step (b) is highly selective with respect to the silicon atoms compared to the carbon atoms, such that only the silicon atoms are effectively dissociated without the carbon atoms being affected, thereby allowing the graphene layer 4 that is intact and having a large surface area to be obtained without requirement of a temperature of up to 1400° C. It can be known that, when the graphene layer 4 prepared by the method of the first embodiment is a graphene monolayer, such graphene layer 4 is particularly suitable for use as a material of the channel of the FETs, and the structure obtained by the method of the first embodiment is also suitable for use as a substrate of an electronic component.

With regard to the cost, the price of the single crystal silicon substrate 2 is more affordable than that of the single crystal silicon carbide substrate, and thus the production cost involved in the method of the present disclosure is lower than that of the thermal decomposition method. In addition, in the method of the present disclosure, formation of the 3C-SiC layer 3 on the surface 21 of the single crystal silicon substrate 2 only requires the carburizing temperature of lower than 1200° C., followed by removing the silicon atoms in the 3C-SiC layer 3 by electrolytic dissociation at the temperature of approximately 772° C., such that the carbon atoms remaining in the 3C-SiC layer 3 are rearranged to form the graphene layer 4, thereby reducing energy consumption during preparation of the graphene layer 4.

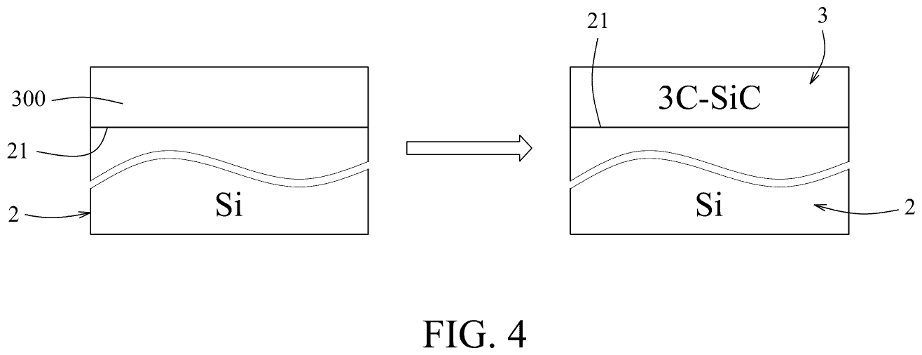

Referring to FIG. 4, a second embodiment of the method for preparing a graphene layer 4 according to the present disclosure and the structure including the graphene layer 4 prepared thereby are substantially similar to those of the first embodiment, except that in step (a) of the method of the second embodiment, the single crystal silicon substrate 2 is placed in a vertical tube reactor (not shown in the figures) and a precursor component containing an iron source, a sulfur source and the carbon source 30 is introduced into the vertical tube reactor, such that during introduction of the precursor component into the vertical tube reactor, the carbon source 30 of the precursor component decomposes and is deposited on the surface 21 of the single crystal silicon substrate 2 to form a carbon ion layer 300, resulting in carbon ions in the carbon ion layer 300 diffusing to the surface 21 of the single crystal silicon substrate 2 during the carburization treatment performed at the carburizing temperature. It should be noted that, the iron source of the precursor component provides a catalytic effect to the carbon source 30 to facilitate decomposition of the carbon source 30 so that the carbon atoms therein form carbon ions at an appropriate temperature, and the sulfur source of the precursor component is capable of assisting the catalytic effect of the iron source so as to enhance the decomposition of the carbon source 30. To be specific, the iron source, the sulfur source and the carbon source 30 of the precursor component are respectively introduced into the vertical tube reactor through pipelines of different lengths, and temperature gradient in the vertical tube reactor is adjusted to allow the iron source and the sulfur source to effectively decompose the carbon source 30, such that the surface 21 of the single crystal silicon substrate 2 is covered with the carbon ions to form the carbon ion layer 300. As a result, the carbon ions diffusing to the surface 21 of the single crystal silicon substrate 2 at the carburizing temperature form the 3C-SiC layer 3. Thereafter, RCA cleaning and drying are conducted in sequence. In step (a) of the method of the second embodiment, the iron source may be selected from the group consisting of ferrocene [Fe(C₅H₅)₂], iron (Fe), and ferrous chloride (FeCl₂). In step (a) of the method of the second embodiment, the sulfur source may be selected from the group consisting of sulfur and thiophene (C₄H₄S).

In summary, in the method for preparing a graphene layer 4 (i.e.,. a continuous graphene monolayer or a plurality of continuous graphene layers) according to the present disclosure, by virtue of implementing step (a), in which the 3C-SiC layer 3 is directly formed on the surface 21 of the single crystal silicon substrate 2 that is relatively inexpensive and that has a relatively large surface area, followed by implementing step (b), in which application of the predetermined voltage in the range described in the foregoing can precisely control the amount of the carbon atoms remaining on the surface of the 3C-SiC layer 3, such that the carbon atoms are rearranged to form the graphene layer 4 that is intact and that has a surface area the same as or substantially the same as that of the surface 21 of the single crystal silicon substrate 2, the production cost and energy consumption during preparation of the graphene layer 4 can be reduced. Therefore, the purpose of the present disclosure can indeed be achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for preparing a graphene layer, comprising the steps of:
(a) subjecting a single crystal silicon substrate to a carburizing treatment at a carburizing temperature ranging from 600° C. to 1200° C., so as to obtain an intermediate structure including the single crystal silicon substrate and a 3C-SiC layer that is formed on a surface of the single crystal silicon substrate; and
(b) placing the intermediate structure in a molten electrolyte of an electrolysis apparatus to permit the intermediate structure to serve as an anode, and applying a predetermined voltage to the anode to cause silicon atoms in the 3C-SiC layer to undergo electrolytic dissociation, such that the silicon atoms move out from lattice positions in the 3C-SiC layer and such that carbon atoms remaining in the lattice positions are rearranged to form the graphene layer, the graphene layer being a continuous graphene monolayer or a plurality of continuous graphene layers.

2. The method as claimed in claim 1, wherein in step (a), the single crystal silicon substrate is placed in a vacuum chamber and a radio frequency voltage is applied across the vacuum chamber to decompose a carbon source in the vacuum chamber, such that the decomposed carbon source diffuses to the surface of the single crystal silicon substrate during the carburization treatment performed at the carburizing temperature.

3. The method as claimed in claim 1, wherein in step (a), the single crystal silicon substrate is placed in a vertical tube reactor and a precursor component containing an iron source, a sulfur source and a carbon source is introduced into the vertical tube reactor, such that during introduction of the precursor component into the vertical tube reactor, the carbon source of the precursor component decomposes and is deposited on the surface of the single crystal silicon substrate to form a carbon ion layer, carbon ions in the carbon ion layer diffusing to the surface of the single crystal silicon substrate during the carburization treatment performed at the carburizing temperature.

4. The method as claimed in claim 2, wherein in step (a), the carbon source includes a hydrocarbon gas selected from the group consisting of methane, ethylene, acetylene, and combinations thereof.

5. The method as claimed in claim 3, wherein in step (a), the carbon source includes a hydrocarbon gas selected from the group consisting of methane, ethylene, acetylene, and combinations thereof.

6. The method as claimed in claim 1, wherein in step (a), the carburizing treatment is performed for a first predetermined time period of not greater than 2 hours.

7. The method as claimed in claim 1, wherein in step (b), the predetermined voltage ranges from 1 V to 10 V, and is applied for a second predetermined time period of not greater than 1 hour.

8. The method as claimed in claim 1, wherein in step (b), the molten electrolyte is prepared from an inorganic chloride compound.

9. A structure, comprising:
a single crystal silicon substrate; and
a graphene layer covering a surface of the single crystal silicon substrate, the graphene layer being a continuous graphene monolayer or a plurality of continuous graphene layers.

10. The structure as claimed in claim 9, further comprising a 3C-SiC layer formed on the surface of the single crystal silicon substrate, the 3C-SiC layer being sandwiched between the single crystal silicon substrate and the graphene layer.

11. The structure as claimed in claim 10, wherein the 3C-SiC layer has a first thickness ranging from 0.4 nm to 20.0 nm.

12. The structure as claimed in claim 9, wherein the graphene layer has a second thickness ranging from 0.3 nm to 20.0 nm.

13. The structure as claimed in claim 9, wherein a surface area of the graphene layer is same as a surface area of the surface of single crystal silicon substrate.
